(19) United States
(12) Patent Application Publication
(10) Pub. No.: US 2008/0061865 A1
(43) Pub. Date: Mar. 13, 2008

(54) Apparatus and method for providing a temperature dependent output signal

(76) Inventor: Heiko Koerner, Soeding (AT)

Correspondence Address: ESCHWEILER & ASSOCIATES LLC, 629 EUCLID AVENUE, SUITE 1000, NATIONAL CITY BUILDING, CLEVELAND, OH, 44114, US

(21) Appl. No.: 11/531,547

(22) Filed: Sep. 13, 2006

(51) Int. Cl. H01L 35/00

(52) U.S. Cl. 327/512; 327/539

(57) ABSTRACT

An apparatus for providing a temperature dependent output signal generates a temperature independent signal on the basis of a supply signal and a control signal and generates the output signal on the basis of the supply signal, the control signal and the temperature independent signal.

### TECHNICAL FIELD

The invention relates to an apparatus and a method for providing a temperature dependent output signal, more particularly, the invention relates to an integrated circuit (IC=Integrated Circuit) bandgap temperature sensor.

### BACKGROUND

Integrated circuits often contain so-called bandgap circuits providing a temperature independent reference voltage according to the band gap principle. For silicon, the band gap voltage is approximately 1.2 Volts at room temperature. In general, the forward voltage V_{F} of a silicon pn-junction is a linear function of an absolute temperature T in degrees Kelvin according to

V_{F}(T)=V_{G0}(1−T/T₀)+V_{BE0}(T/T₀)+(nkT/q)ln(T₀/T)+(kT/q)ln(I/I₀),

where k is the Boltzmann constant, q is the electron charge, V_{G0} is the bandgap voltage at absolute zero temperature, V_{BE0} is the bandgap voltage at temperature T₀ and current I₀, I is the forward current and n is a device-dependent constant.

The temperature dependent forward voltage V_{F} is useful as a basis for a stable and relatively linear temperature sensor. One such type of a conventional temperature sensor typically involves a bandgap circuit that generates a current proportional to absolute temperature (I_{PTAT}) by e.g. using a voltage difference of the pn-junctions of two diodes with different current densities. As mentioned before, the forward voltage V_{F} of a diode is proportional to the absolute temperature T. A differential forward voltage ΔV_{F} obtained by using the forward voltage difference of two diodes D1 and D2 at two currents I_{D1}, I_{D2}

ΔV_{F}(T)=(kT/q)ln(I_{D1}/I_{D2})

is typically very small, so an amplification circuit is used to create a more convenient temperature coefficient for the temperature sensor.

A current proportional to the absolute temperature I_{PTAT,1}, which, after being scaled e.g. by a current mirror or other suitable arrangements to a current I_{PTAT,2}, is output to a temperature sensor resistor to provide a temperature dependent output voltage V_{PTAT} of the temperature sensor. Since the temperature sensor resistor is of the same type as a resistor used in the bandgap circuit to generate the current I_{PTAT,1} and/or I_{PTAT,2} the output V_{PTAT} of the temperature sensor circuit is linearly proportional to temperature T.

Ideally, a drain current I_{PTAT,1} of a first transistor T1 of the current mirror is equal to a drain current I_{PTAT,2} of a second transistor T2 of the current mirror. Using suitably high supply voltages V_{BAT} and accordingly dimensioned transistors T1 and T2 or a cascode arrangement, e.g. a third transistor having its drain connected to the source of the second transistor T2, the error between the two currents I_{PTAT,1} and I_{PTAT,2} can be kept relatively small. However, with decreasing supply voltage V_{BAT}, this error can become very high and can, therefore, negatively influence the measured temperature voltage V_{PTAT}.

### SUMMARY

According to an embodiment, an apparatus for providing a temperature dependent output signal may comprise a supply signal input, an output for the temperature dependent output signal, a first transistor having a control terminal for a control signal, a first terminal connected to the supply signal input and a second terminal for a temperature independent signal, a second transistor having a control terminal for the control signal, a first terminal connected to the supply signal input and a second terminal, a signal adjustment element comprising a control terminal for an adjustment signal, a first terminal connected to the second terminal of the second transmitter and a second terminal connected to the output and a first control circuit comprising a first input for the reference signal, a second input for a signal at the second terminal of the second transistor and an output for the adjustment signal.

### BRIEF DESCRIPTION OF THE DRAWINGS

Embodiments of the present invention are explained in more detail below with respect to the accompanying drawings, in which:

FIG. 1 shows a circuit diagram of a conventional bandgap temperature sensor IC;

FIG. 2 shows a graph depicting a linear dependency of a temperature dependent output voltage V_{PTAT} from the temperature T of the bandgap temperature sensor IC of FIG. 1;

FIG. 3 shows an integrated circuit of a bandgap temperature sensor according to an embodiment;

FIG. 4a shows a diagram depicting a comparison of the dependencies of the temperature dependent output voltage V_{PTAT} of a conventional IC bandgap temperature sensor and a bandgap temperature sensor according to an embodiment; and

FIG. 4b shows a diagram depicting a comparison of the dependencies of the bandgap voltage V_{BG} of a conventional IC bandgap temperature sensor and a bandgap temperature sensor according to an embodiment.

### DETAILED DESCRIPTION

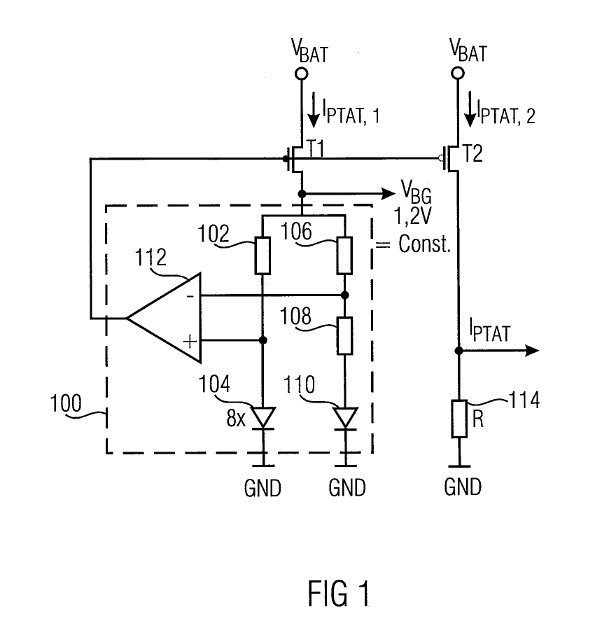

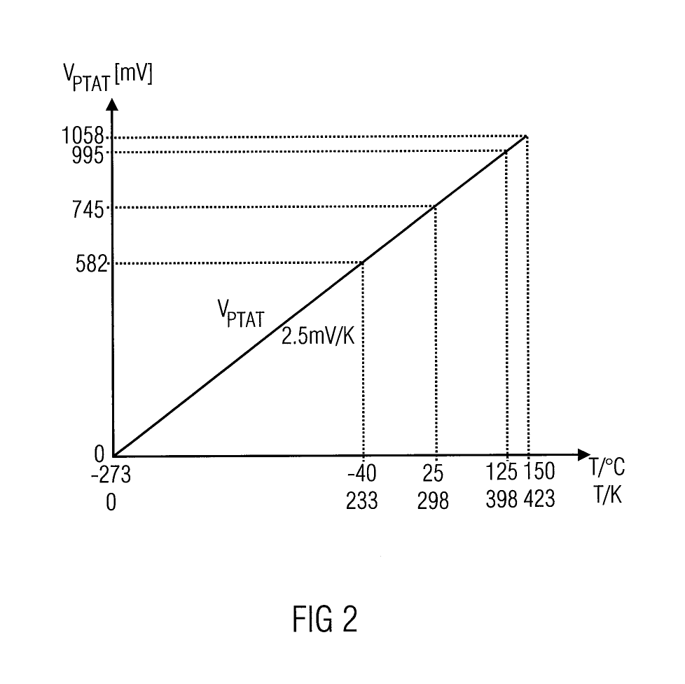

Before referring to a bandgap temperature sensor according to an embodiment, a conventional bandgap temperature sensor is discussed referring to FIG. 1 and FIG. 2.

FIG. 1 shows a circuit diagram of an integrated circuit illustrating a conventional bandgap temperature sensor. The circuit comprises a first PMOS-transistor T1 having a drain terminal connected to a supply voltage V_{BAT} and a source terminal connected to an input of a control circuit 100. The input terminal of the control circuit 100 is connected to a parallel circuit comprising a first branch comprising a series circuit of a resistor 102 and a first diode 104 and a second branch comprising a series circuit of a resistor 106, a resistor 108 and a second diode 110. A first terminal of the resistor 102 is connected to the input terminal of the control circuit 100 and a second terminal of the resistor 102 is connected to a non-inverted input of an operational amplifier 112 and to a first terminal of the first diode 104. A second terminal of the first diode 104 is connected to ground potential GND. Further, a first terminal of the resistor 106 is connected to the input terminal of the control circuit 100 and a second terminal of the resistor 106 is connected to an inverted input of the operational amplifier 112 and to a first terminal of the resistor 108. A second terminal of the resistor 108 is connected to a first terminal of the second diode 110 and a second terminal of the diode 110 is also connected to ground potential. An output of the operational amplifier 112 is connected to a control terminal of the first transistor T1 and to a control terminal of a second PMOS-transistor T2. Further, a voltage V_{BG} can be measured at the source terminal of transistor T1 across the parallel circuit against ground potential GND. The drain terminal of the second PMOS-transistor T2 is connected to the supply voltage V_{BAT} and the source terminal of the second transistor T2 is connected to a first terminal of a resistor 114, whose second terminal is connected to ground. A voltage that can be measured across the resistor 114 determines the temperature dependent output voltage V_{PTAT}.

As previously discussed herein, many conventional temperature sensors typically include some type of a bandgap circuit coupled between an upper supply voltage (e.g. V_{BAT}) and a lower supply voltage (e.g. GND). In the particular conventional circuit arrangement depicted in FIG. 1, the bandgap circuit comprises the first PMOS-Transistor T1 and the control circuit 100, wherein in the control circuit 100 the pn-junction of the first diode 104 is e.g. eight times wider than that of the second diode 110. The voltage V_{BG} is kept constant to approximately 1.2 V over a wide temperature and supply voltage range by the control loop comprising the control circuit 100 and the transistor T1. The regulated source current I_{PTAT,1} of transistor T1 which controls the voltage V_{BG} is proportional to the absolute temperature T. Further, the current I_{PTAT,1} can be mirrored by the second transistor T2 to a current I_{PTAT,2} and is converted into a temperature dependent voltage V_{PTAT} across the resistor 114. Hence, the output voltage V_{PTAT} is also proportional to the absolute temperature T. As a result thereof the bandgap circuit depicted in FIG. 1 can be used as a temperature sensor.

A relationship between temperature T and the temperature dependent voltage V_{PTAT} is depicted in FIG. 2. In this example, the resistor 114 is chosen such that the temperature sensor depicted in FIG. 1 offers a slope of 2.5 mV/K.

As can be seen from FIG. 2 at-the absolute zero temperature, i.e. −273° C., the voltage V_{PTAT} equals zero. This is due to the fact that in this case the difference between the two forward voltages of the silicon pn-junctions of the two diodes 104 and 110 is zero. Since the pn-junction of the diode 104 is approximately eight times wider than the pn-junction of diode 110, the difference of the two respective forward voltages is directly proportional to the temperature T. The operational amplifier 112 forces the voltage at its input terminals to be equal by controlling the gate voltages of the two PMOS-transistors T1 and T2 and, hence, the drain currents there through. Since the devices T1 and T2 are both of unit size and share a common gate voltage, the drain current is the same in both devices. In this manner, the circuitry in FIG. 1 generates a current proportional to absolute temperature, shown as I_{PTAT,1} which is mirrored as I_{PTAT,2} by transistor T2.

As already mentioned before the two PMOS-transistors T1 and T2 form a current mirror. The source terminal of the left transistor T1 is connected to the regulated temperature independent constant bandgap voltage V_{BG} and the source terminal of the right PMOS-transistor T2 is connected to the temperature proportional output voltage V_{PTAT}. Hence, depending on the temperature T, the source terminals of the two transistors T1 and T2 can hold different potentials, which can lead to an error for the output voltage V_{PTAT} due to the limited internal resistance of the current sources, i.e. the transistors T1 and T2. Ideally, the drain current I_{PTAT,1} is equal to the drain current I_{PTAT,2}. For high supply voltages V_{BAT} and accordingly dimensioned transistors T1 and T2 or with the use of a cascode arrangement, the error can be kept relatively small. However, with a decreasing supply voltage V_{BAT}, this error can get very large and, hence, lead to an error measuring V_{PTAT}. This is due to the fact that for a decreasing supply voltage V_{BAT} and the temperature independent constant V_{BG}=1.2 V the transistor T1 starts to leave its saturation area, while transistor T2 still remains in the saturation area. Hence, the drain-source conductance (GDS) differs for both transistors.

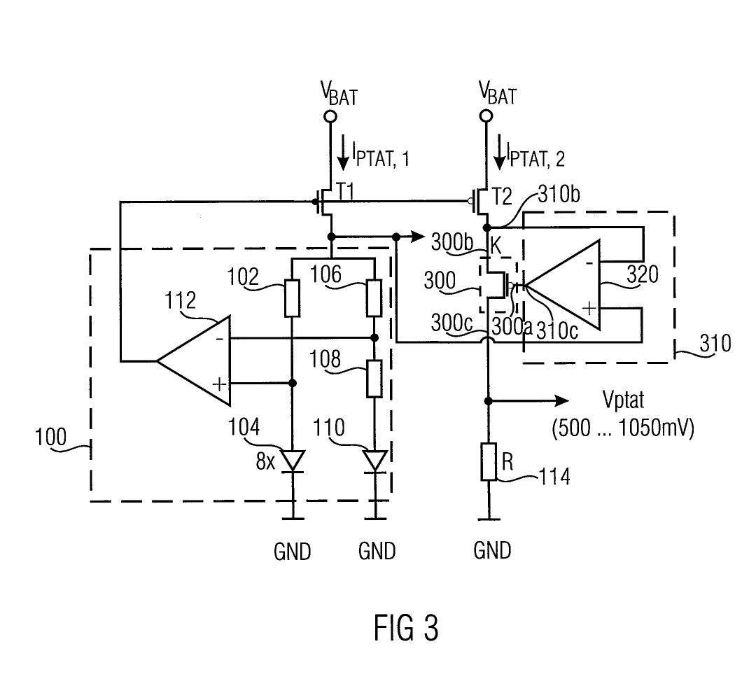

This disadvantage can be reduced by modifying the circuit of FIG. 1 according to an embodiment. FIG. 3 shows a modified bandgap temperature sensor IC for a large range of supply voltages according to an embodiment.

Based on the bandgap temperature sensor circuit of FIG. 1, FIG. 3 shows a modified bandgap temperature sensor circuit including a signal adjustment element 300 comprising a control terminal 300a for an adjustment signal. The signal adjustment element 300 is connected to the source terminal of the second PMOS-transistor T2 with a first terminal 300b and connected to the output terminal with a second terminal 300c where the temperature dependant voltage V_{PTAT} is present. Further, FIG. 3 shows a control circuit 310 comprising a first input 310a for the temperature independent signal or voltage V_{BG}, a second input 310b for the source voltage of the second transistor T2 and an output 310c connected to the control terminal 300a for the adjustment signal.

The control circuit 310 comprises an operational amplifier 320 comprising a non-inverted input terminal, which is connected to the temperature independent voltage V_{BG} provided at the source terminal of the PMOS-transistor T1. The inverted input of the operational amplifier 320 is connected to the source terminal of the second PMOS-transistor T2.

The signal adjustment element 300 comprises a further PMOS-transistor T3, whose control terminal is connected to the output of the operational amplifier 320. The drain terminal of transistor T3 is connected to the source terminal of transistor T2, whereas the source terminal of transistor T3 is connected to the output terminal providing the temperature dependent output voltage V_{PTAT}, hence forming a cascode arrangement to the current mirror comprising the transistors T1 and T2.

The first PMOS transistor T1 and the control circuit 100 operate up to a supply voltage V_{BAT} of 1.2 V plus a saturation voltage V_{SAT} of the PMOS-transistor T1. Since there is more headroom for the voltage at the source terminal of transistor T2, the third PMOS-transistor T3 is added, which is controlled via the control circuit 310. The control circuit 310 comprises the operational amplifier 320 whose non-inverted input is terminal is connected to the source terminal of the first transistor T1 carrying the temperature independent voltage V_{BG} and whose inverted input terminal is connected to the source terminal of the second transistor T2. The operational amplifier 320 controls the control terminal of the additional PMOS-transistor T3. The purpose of this modification according to an embodiment is that the source potential of the transistor T2 can be regulated towards the temperature independent potential V_{BG} (e.g. 1.2 V). Hence, both the transistors T1 and T2 can have the same potential on their source terminals, respectively. Therefore, both transistors T1 and T2 always have at least approximately the same internal resistance or alternately at least approximately the same drain-source conductance. The internal resistances of T1 and T2 can get small, but not essentially different from each other. Small differences could only be due to potential mismatches in the circuit depicted in FIG. 3, e.g. due to slightly different physical parameters of the transistors T1 and T2.

According to an embodiment the two transistors T1 and T2 can be operated up to the edge of their saturation areas, respectively, and, hence, the integrated bandgap temperature sensor circuit depicted in FIG. 3 can be operated to voltages down to V_{BG}+V_{SAT}, where V_{SAT} denotes the saturation voltages of T1 and T2. Typically, V_{BG}+V_{SAT} can be 1.3 V to 1.5 V.

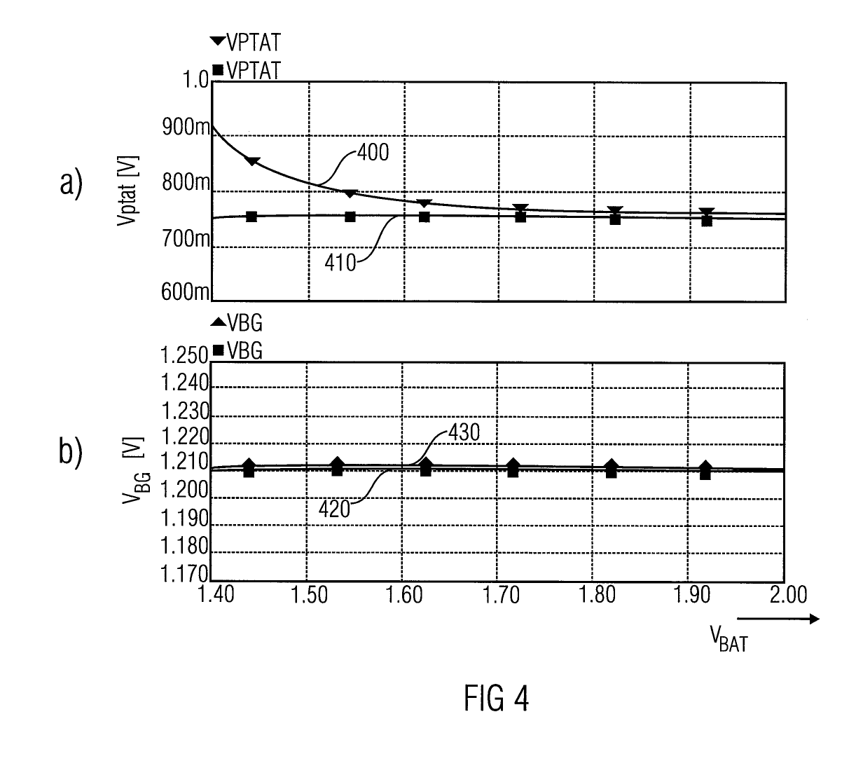

FIG. 4a shows a diagram depicting a comparison of the dependencies of the temperature dependent output voltage V_{PTAT} of a conventional IC bandgap temperature sensor and a bandgap temperature sensor according to an embodiment.

FIG. 4a shows a curve 400 related to the conventional temperature sensor and a curve 410 related to the modified temperature sensor according to an embodiments. FIG. 4a shows that in the case of the conventional bandgap temperature sensor circuit, the voltage V_{PTAT} rises undesirably with a decreasing supply voltage V_{BAT}. At a supply voltage V_{BAT=}1.4 V, the curve 400 of the voltage V_{PTAT} of the conventional temperature sensor reveals a large error (>100 mV). This error of the voltage V_{PTAT} can translate to an error in the measured absolute temperature of more than 10K.

Ideally, the value of the voltage V_{PTAT} should run parallel to the temperature axis. This desired behavior can be observed for the curve 410 of the modified temperature sensor according to an embodiment.

FIG. 4b shows a diagram depicting a comparison of the dependencies of the bandgap voltage V_{BG} of a conventional IC bandgap temperature sensor and a bandgap temperature sensor according to an embodiment. FIG. 4b shows a curve 420 related to the conventional temperature sensor and a curve 430 related to the modified temperature sensor according to an embodiment.

As can be seen, the behavior of the bandgap voltage V_{BG} remains unchanged from the modification of the temperature sensor circuit.

According to an embodiments, a more reliable temperature sensor can be realized. This is particularly true for low supply voltages V_{BAT} in the range of 1.3 to 1.5 Volts. It may be advantageous that a temperature sensor according to an embodiment can be operated at very low supply voltages which can, for example, yield a longer battery life for mobile devices or enable operation in devices where only a small supply voltage is available (e.g. passive RFID tags, RFID=Radio Frequency Identification). According to an embodiment, this can be achieved by connecting the third transistor T3 to the source terminal of the second transistor T2 and by controlling the transistor T3 by a control loop in order to provide the temperature independent bandgap voltage V_{BG} at the source terminal of the second transistor T2. Therefore, the transistors T1 and T2 obtain at least approximately the same potential at their source terminals, respectively.

With respect to further embodiments, different realizations of the used transistors are possible. For example, bipolar transistors can also be used. In particular, the usage of CMOS-transistors is also possible. Relative to the respective embodiment, the transistor source terminals relate to emitter or source terminals, respectively, the transistor sink terminals relate to the collector or drain terminals, respectively and the transistor control terminals relate to the base or gate terminals, respectively.

Depending on certain implementation requirements of the methods according to an embodiment, the methods can be implemented in hardware or in software. The implementation can be performed using a digital storage medium, in particular a disk, DVD or a CD having electronically readable control signals stored thereon, which cooperate with a programmable computer system such that the methods are performed. Generally, therefore, in one embodiment, in a computer program product with a program code stored on a machine readable carrier, the program code is operative for performing the methods when the computer program product runs on a computer. In other words, the methods are, therefore, a computer program having a program code for performing at least one of the methods when the computer program runs on a computer.

What is claimed is:

1. An apparatus for providing a temperature dependent output signal, the apparatus comprising:
a supply signal input;
an output for the temperature dependent output signal;
a first transistor comprising a control terminal for a control signal, a first terminal connected to the supply signal input and a second terminal for a temperature independent signal;
a second transistor comprising a control terminal for the control signal, a first terminal connected to the supply signal input and a second terminal;
a signal adjustment element comprising a control terminal for an adjustment signal, a first terminal connected to the second terminal of the second transistor and a second terminal connected to the output, and a first control circuit comprising a first input for the temperature independent signal, a second input for a signal at the second terminal of the second transistor and an output for the adjustment signal.

2. An apparatus according to claim 1, further comprising:
a second control circuit for regulating the control signal comprising a first terminal for the temperature independent signal (V_{BG}), a second terminal for a reference signal and an output terminal for the control signal for the first and second transistor.

3. An apparatus according to claim 1, wherein the first control circuit comprises an operational amplifier comprising a non-inverted input terminal connected to the first input of the first control circuit and an inverted input connected to the second input of the first control circuit and comprising an output connected to the output of the first control circuit.

4. An apparatus according to claim 1, wherein the signal adjustment element comprises a transistor comprising a control terminal connected to the control terminal of the adjustment element, a first terminal connected to the second terminal of the second transistor and a second terminal connected to the output.

5. An apparatus according to claim 2, wherein the second control circuit comprises an operational amplifier comprising an output terminal for the control signal.

6. An apparatus according to claim 5, wherein the second control circuit further comprises a parallel circuit connected between the temperature independent signal and the reference signal, wherein a first branch of the parallel circuit comprises a series circuit comprising a first resistor and a first diode, and a second branch of the parallel circuit comprises a series circuit comprising a second resistor, a third resistor and a second diode.

7. An apparatus according to claim 6, wherein a first terminal of the first resistor of the first branch of the parallel circuit is connected to the second terminal of the first transistor, and the second terminal of the first resistor is connected to the non-inverted input of the operational amplifier, and wherein a first terminal of the second resistor of the second branch of the parallel circuit is connected to the second terminal of the first transistor and a second terminal of the second resistor of the second branch of the parallel circuit is connected to the inverted input of the operational amplifier.

8. An apparatus according to claim 6, wherein the pn-junction of the first diode of the parallel circuit is wider than the pn-junction of the second diode of the parallel circuit.

9. An apparatus for providing a temperature dependent output signal, the apparatus comprising:
means for generating a temperature independent signal on the basis of a supply signal and a control signal; and
means for generating the output signal on the basis of the supply signal, the control signal and the temperature independent signal.

10. An apparatus according to claim 9, wherein the means for generating the temperature independent signal comprise means for providing the control signal on the basis of a temperature dependent forward voltage of a pn-junction and the temperature independent signal.

11. An apparatus according to claim 9, wherein the means for generating the temperature independent signal comprise a transistor means for amplifying the control signal to a temperature dependent signal.

12. An apparatus according to claim 9, wherein the means for generating the output signal comprise:
a second transistor means for providing an output source signal on the basis of the control signal and the supply signal;
a signal adjustment means for adjusting the output signal of the second transistor means on the basis of a second control signal; and
a control means for controlling the second control signal for the signal adjustment means on the basis of the temperature independent signal and the output signal of the second transistor means.

13. An apparatus according to claim 12, wherein the signal adjustment means comprises a transistor means in a cascode arrangement with respect to the second transistor means.

14. A method for providing a temperature dependent output signal, the method comprising the following steps:
generating a temperature independent signal on the basis of a supply signal and a control signal; and
generating the output signal on the basis of the supply signal, the control signal and the temperature independent signal.

15. A method according to claim 14, wherein the step of generating the temperature independent signal comprises a step of generating the control signal on the basis of the temperature independent signal and a temperature dependent forward voltage of a pn-junction.

16. A method according to claim 14, wherein the step of generating the output signal further comprises the following steps:
providing a source signal on the basis of the control signal and the supply signal;
adjusting the source signal on the basis of a second control signal; and
controlling the second control signal for adjusting the source signal on the basis of the temperature independent signal and the source signal.

17. A Computer program product comprising a program code stored a computer-readable medium for performing the following steps when the computer program runs on a computer:
generating a temperature independent signal on the basis of a supply signal and a control signal; and
generating the output signal on the basis of the supply signal, the control signal and the temperature independent signal.

18. A Computer program product according to claim 17, wherein the step of generating the temperature independent signal comprises a step of generating the control signal on the basis of the temperature independent signal and a temperature dependent forward voltage of a pn-junction.

19. A Computer program product according to claim 17, wherein the step of generating the output signal further comprises the following steps:
providing a source signal on the basis of the control signal and the supply signal;
adjusting the source signal on the basis of a second control signal; and
controlling the second control signal for adjusting the source signal on the basis of the temperature independent signal and the source signal.
